(19) United States
(12) Patent Application Publication
(10) Pub. No.: US 2012/0281386 A1
(43) Pub. Date: Nov. 8, 2012

(54) EASILY SOLDERABLE SHIELD CASE FOR ELECTROMAGNETIC WAVE SHIELDING

(75) Inventor: SUN-KI KIM, Gunpo-si (KR)

(73) Assignee: Joinset Co., Ltd., Ansan-si (KR)

(21) Appl. No.: 13/551,359

(22) Filed: Jul. 17, 2012

Related U.S. Application Data
(63) Continuation of application No. PCT/KR2011/000624, filed on Jan. 28, 2011.

(30) Foreign Application Priority Data
Feb. 3, 2010 (KR) 10-2010-0009977
Jan. 28, 2011 (KR) 10-2011-0008784

(51) Int. Cl. H05K 9/00

(52) U.S. Cl. 361/818

(57) ABSTRACT

An easily soldered shield case for electromagnetic-wave shielding comprises: a metal main body in the shape of a box of which the bottom surface is open; a flange which is formed extending integrally outward or inward from the open edge of the main body; a plurality of through holes formed along the flange or a plurality of recesses formed along the rear surface of the flange; and a solder member which is stably placed on the through holes or the recesses and projects in the thickness direction of the flange, wherein the shield case is mounted on a printed circuit board and the solder member is electrically and mechanically joined to the printed circuit board by means of soldering.

### REFERENCE TO RELATED APPLICATIONS

This is a continuation of pending International Patent Application PCT/KR2011/000624 filed on Jan. 28, 2011, which designates the United States and claims priority of Korean Patent Application No. 10-2010-0009977 filed on Feb. 3, 2010, and Korean Patent Application No. 10-2011-0008784 filed on Jan. 28, 2011, the entire contents of which are incorporated herein by reference.

### FIELD OF THE INVENTION

The present invention relates to a shield case for electromagnetic wave shielding, and more particularly, to a shield case for electromagnetic wave shielding, which is soldered to a ground pattern of a printed circuit board. In addition, the present invention relates to a shield case for electromagnetic wave shielding, which is appropriate for a reflow soldering process and a surface mount process using vacuum pickup so as to improve productivity and reworking efficiency.

### BACKGROUND OF THE INVENTION

In general, a high frequency electronic part or module is covered with a shield case for electromagnetic wave shielding, and then, the shield case is electrically and mechanically connected to a ground pattern of a printed circuit board, in order to prevent electromagnetic waves from being emitted out of the high frequency electronic part or module or to shield the high frequency electronic part or module from external electromagnetic waves.

In this case, the shield case may include an electrically conductive member such as a metal sheet or electrically insulating polymer resin plated with a metal to block electromagnetic waves, and has a box shape with at least one opening to cover electronic parts or modules mounted on the printed circuit board. Such a shield case for electromagnetic wave shielding is electrically and mechanically connected to a ground pattern of a printed circuit board by using soldering or physical coupling with a metal screw or a metal clip.

Referring to FIG. 1A, a shield case 10 for electromagnetic wave shielding is formed by pressing or drawing a metal sheet. The lower end of a side wall of the shield case 10 may be soldered directly to a ground pattern of a printed circuit board, or the end of the side wall may be inserted in a metal clip installed in advance on a ground pattern. In this case, the soldering of the lower end may be reflow soldering using solder or solder cream.

Referring to FIG. 1B, a shield case 20 for electromagnetic wave shielding includes tips 21 and 22 protruding from the lower end of a side wall of thereof. The tips 21 and 22 are integrally formed with the shield case 20. When the shield case 20 is soldered to a ground pattern of a printed circuit board, the tips 21 and 22 are inserted in holes formed in the ground pattern.

Referring to FIG. 10, a shield case 30 for electromagnetic wave shielding includes an electromagnetic wave shield partition 31 to separate high frequency electronic parts or modules from each other. The lower end of the electromagnetic wave shield partition 31 is soldered to a ground pattern of a printed circuit board.

As described above, a shield case for electromagnetic wave shielding is installed on a ground pattern of a printed circuit board by directly soldering the lower end of a side wall of the shield case to the ground pattern.

However, such metal shield cases are inappropriate for a surface mount process using vacuum pickup and a reflow soldering process using solder cream or flux, and thus, it is difficult to ensure the productivity and quality of the metal shied cases. For example, the lower end of a side wall of a shield case to be soldered may have a thickness ranging from about 0.1 mm to about 0.25 mm, which is equal to the thickness of a metal sheet used to form the shield case. In this case, when the shield case is large, it may be difficult to maintain the lower end of the shield case in a horizontal position, which jeopardizes the reliability of reflow soldering through a surface mount process. In addition, an airflow generated during reflow soldering may move a shield case, which also jeopardizes the reliability of reflow soldering. In addition, since a shield case should be entirely plated with a soldering metal such as stanuum, for soldering of the lower end of the shield case, manufacturing costs thereof are increased. In addition, after the lower end of a side wall of a shield case is entirely soldered, reworking of the shield case may be difficult.

A shield case may be installed on a ground pattern by fitting the shield case in a metal clip installed in advance on the ground pattern. For reference, a clip for fixing a shield case is disclosed in Korean Patent Registration No. 10-886591.

However, a metal clip for fixing a shield case is lightweight and has a length greater than a width thereof, and thus, is susceptible to shaking and torsion during reflow soldering. Thus, even when just one of metal clips is not in position, inserting of a shield case having predetermined dimensions may be difficult. In addition, when a reflow flowing process is performed on a metal clip, solder may protrude over a predetermined level from the metal clip. In this case, a shield case may not be inserted down to the lower end of the metal clip. A metal clip and the bottom surface of a shield case should be reliably adhered to a ground pattern to improve electromagnetic wave shield effect. Thus, when the shield case formed of a metal is not reliably attached thereto, the electromagnetic wave shield effect may be degraded. In addition, after soldering of metal clips, a shield case is manually fitted in the metal clips, which reduces productivity.

According to a technology using SNAPSHOT®, manufactured by W. L. Gore & Associates, Inc. of the United States, a punctured material formed of an insulating heat resistant polymer through injection molding is treated with a metal, and is then installed on solder spheres formed on a printed circuit board.

However, since the punctured material is thicker than a shield case formed from a metal foil, the punctured material is inappropriate to be used a small device such as a mobile device. In addition, the treating of the punctured material with a metal is expensive. Furthermore, it is difficult to install the punctured material on the solder spheres formed in advance on the printed circuit board. Moreover, reworking of the punctured material is difficult, and the thermal conductivity thereof is low.

Typical shield cases for electromagnetic wave shielding may be formed by performing successive pressing processes on a metal sheet having a predetermined strength, such as a stainless steel sheet. In this case, the positions of electromagnetic wave shield partitions should be changed according to the shapes of electromagnetic wave shield areas. To this end, press molds used in the pressing processes should be modified.

### SUMMARY OF THE INVENTION

An object of the present invention is to provide a shield case for electromagnetic wave shielding, which includes solder members to be efficiently soldered to a ground pattern of a printed circuit board.

Another object of the present invention is to provide a shield case for electromagnetic wave shielding, which is appropriate for a surface mount process using vacuum pickup and a reflow soldering process using solder cream or flux and which improves productivity.

Another object of the present invention is to provide an easily solderable shield case for electromagnetic wave shielding, which is electrically, mechanically, and reliably connected to a ground pattern of a printed circuit board so as to improve electromagnetic wave shielding effect and mechanical coupling strength.

Another object of the present invention is to provide an easily solderable shield case for electromagnetic wave shielding, which includes an electromagnetic wave shield partition that elastically, electrically, and reliably contacts a ground pattern and that economically form an electromagnetic wave shield area.

Another object of the present invention is to provide an easily solderable shield case for electromagnetic wave shielding, which is prevented from being shaken and misaligned during reflow soldering, thereby increasing production yield.

Another object of the present invention is to provide an easily solderable shield case for electromagnetic wave shielding, which efficiently emit heat and facilitates visual inspection of an electronic part installed in the shield case before and after soldering.

Another object of the present invention is to provide a shield case for electromagnetic wave shielding, which makes it possible to simultaneously perform a reflow soldering process on both an electronic part disposed inside the shield case and an electronic part disposed outside the shield case under the same reflow soldering condition.

Another object of the present invention is to provide an easily solderable shield case for electromagnetic wave shielding, which can be efficiently reworked.

Another object of the present invention is to provide an easily solderable shield case for electromagnetic wave shielding, which is economically and reliably soldered to a large printed circuit board regardless of the structure and dimensions thereof.

According to an aspect of the present invention, there is provided an easily solderable shield case for electromagnetic wave shielding, including: a main body formed of a metal, and having a box shape with a lower opening; a flange extending outward or inward from an edge of the lower opening of the main body, and integrally formed with the main body in one piece; a plurality of through holes arrayed along the flange or a plurality of recesses arrayed along a back surface of the flange; and a plurality of solder members placed in the through holes or the recesses and protruding in a thickness direction of the flange, wherein the shield case is mounted on a ground pattern of a printed circuit board, and the solder members are electrically and mechanically connected to the ground pattern through soldering.

According to another aspect of the present invention, there is provided an easily solderable shield case for electromagnetic wave shielding, including: a main body formed of a metal, and having a box shape with a lower opening; a flange extending outward or inward from an edge of the lower opening of the main body, and integrally formed with the main body in one piece; a plurality of through holes arrayed along the flange or a plurality of recesses arrayed along a back surface of the flange; and a plurality of solder members appropriate for reflow soldering, which are placed in the through holes or the recesses, and protrude in a thickness direction of the flange.

According to another aspect of the present invention, there is provided an easily solderable shield case for electromagnetic wave shielding, including: a main body formed of a metal, and having a box shape with a lower opening; a flange extending outward or inward from an edge of the lower opening of the main body, and integrally formed with the main body in one piece; a plurality of through holes arrayed along the flange or a plurality of recesses arrayed along a back surface of the flange; and a plurality of solder members placed in the through holes or the recesses and protruding in a thickness direction of the flange, wherein the solder members are electrically and mechanically connected to a ground pattern of a printed circuit board through a reflow soldering process and a surface mount process using vacuum pickup.

According to another aspect of the present invention, there is provided an easily solderable shield case for electromagnetic wave shielding, including: a main body formed of a metal, and having a box shape with an upper opening and a lower opening; an electrically conductive cover that covers the upper opening of the main body and is removable therefrom; a flange extending outward or inward from an edge of the lower opening of the main body, and integrally formed with the main body in one piece; a plurality of through holes arrayed along the flange or a plurality of recesses arrayed along a back surface of the flange; and a plurality of solder members placed in the through holes or the recesses and protruding in a thickness direction of the flange, wherein the main body is mounted on a ground pattern of a printed circuit board, and is electrically and mechanically connected to the printed circuit board through a soldering process using the solder members, and the electrically conductive cover is installed on the main body after the soldering process.

Under the above-described structure, since solder cream or flux formed on a ground pattern of a printed circuit board, and the solder members protruding from the through holes or recesses of the flanges of the shield case are molten and electrically and mechanically adhered to each other through a soldering process to thereby decrease electrical contact resistance thereof, electromagnetic wave shield efficiency and mechanical coupling strength of the shield case are improved.

In addition, since the solder members are placed in advance in the through holes or recesses, reflow soldering can be reliably and economically carried out on the shield case through a surface mount process, regardless of the structure and dimensions of the shield case.

In addition, since the flanges have a large area, variously shaped through holes or through holes opened at a side thereof can be efficiently formed in the flanges. Furthermore, recesses can be formed in the back surfaces of the flanges. Thus, the solder members can be efficiently placed in the through holes or recesses.

In addition, since the flanges disposed on the bottom of the shield case are wide, shaking and misaligning of the shield case during surface mount and reflow soldering processes are suppressed, thereby improving productivity and quality reliability.

In addition, since the electromagnetic wave shield partition disposed on the back surface of the shied case is formed of electrically conductive rubber having elasticity and heat resistance, the electromagnetic wave shield partition is appropriate for reflow soldering, and elastically and reliably contact a ground pattern after the reflow soldering.

In addition, since the upper opening is disposed in the top of the main body, heat generated during a reflow soldering process is transferred to the inside of the shield case, and thus, an electronic part disposed outside the shield case and an electronic part disposed inside the shield case have a similar soldering temperature, so that the reflow soldering process can be simultaneously performed on both the electronic parts inside and outside the shield case, thereby improving productivity.

In addition, since the main body is formed from a metal sheet, the shield case can be economically formed through pressing or drawing. In addition, since the main body has excellent thermal conductivity, the flanges and the solder members are formed on only a desired portion of the main body, the shield case can be miniaturized to be appropriate for a small electronic device.

In addition, since the heat resistant polymer film including a solderable metal layer may be adhered to a surface of a metal sheet, even when the shield case is formed of a metal inappropriate for soldering, the solder members disposed in the through holes or recesses disposed in the flanges can be soldered to the solderable metal layer and solder cream.

In addition, since a protruded portion of the solder members are received by the solderable via holes or recesses formed in a ground pattern, moving and misaligning of the shield case are suppressed during reflow soldering, thereby ensuring quality of the shield case.

In addition, the solder members disposed on the flanges can be removed using heat after reflow soldering, thereby facilitating a reworking process.

### BRIEF DESCRIPTION OF THE DRAWINGS

FIGS. 1A, 1B, and 1C are perspective views illustrating shield cases for electromagnetic wave shielding in the related art.

FIG. 2 is a perspective view illustrating a shield case that is easily soldered and is used for electromagnetic wave shielding, according to an embodiment of the present invention.

FIG. 3 is a perspective view illustrating a shield case for electromagnetic wave shielding, which includes a modified example of flanges of FIG. 2.

FIG. 4 is a perspective view illustrating a shield case for electromagnetic wave shielding, which includes another modified example of the flanges of FIG. 2

FIG. 5 is a partial perspective view illustrating a shield case for electromagnetic wave shielding, which includes a modified example of through holes of FIG. 1

FIG. 6 is a cross-sectional view taken along line A-A′ of FIG. 2.

FIG. 7 is a perspective view illustrating a shield case that is easily soldered and is used for electromagnetic wave shielding, according to another embodiment of the present invention.

FIG. 8 is a perspective view illustrating a state in which the shield case (400) of FIG. 7 is attached through a reflow soldering process to solder cream formed on a ground pattern of a printed circuit board.

FIG. 9 is a perspective view illustrating the lower part of a shield case for electromagnetic wave shielding, according to another embodiment of the present invention.

FIG. 10 is a perspective view illustrating a shied case for electromagnetic wave shielding, according to another embodiment of the present invention.

FIG. 11 is a perspective view illustrating a shied case for electromagnetic wave shielding, according to another embodiment of the present invention.

FIG. 12 is a perspective view illustrating a shied case for electromagnetic wave shielding, according to another embodiment of the present invention.

FIG. 13 is a perspective view illustrating a shied case for electromagnetic wave shielding, according to another embodiment of the present invention.

### DETAILED DESCRIPTION OF THE INVENTION

Embodiments of the present invention will be described below in more detail with reference to the accompanying drawings.

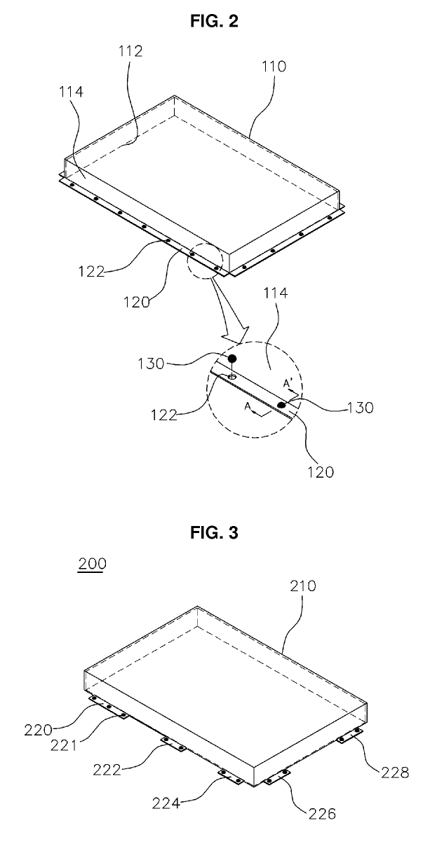

FIG. 2 is a perspective view illustrating a shield case 100 that is easily soldered and is used for electromagnetic wave shielding, according to an embodiment of the present invention.

The shield case 100 includes a main body 110, a plurality of flanges 120, a plurality of through holes 122, and a plurality of solder members 130 such as solder balls. The main body 110 is formed of an electrically conductive metal, and has a box shape with an opening 112 in a surface thereof (in a lower surface in the current embodiment). The flanges 120 extend outward or inward along edges of the opening 112, and are integrally formed with the main body 110 in one piece. The through holes 122 are arrayed along the flanges 120. The solder members 130 are placed in the through holes 122, and protrude in a thickness direction of the flanges 120.

The shield case 100 configured as described above is picked up with the top surface of the main body 110 being held through a vacuum pickup process, and the back surfaces of the flanges 120 are installed, through a surface mounting process, on solder cream or flux formed on a ground pattern of a printed circuit board. After that, the solder members 130 and the ground pattern are soldered to each other with the solder cream or flux therebetween through a reflow soldering process, and thus, are electrically and mechanically connected to each other, thereby mechanically protecting electronic parts or modules disposed within the shield case 100 from the outside thereof, and electrically shielding the electronic parts or modules from external electromagnetic waves.

Since the flanges 120 are separated from one another at the four corners of the main body 110, the flanges 120 may be formed by continuously pressing a metal sheet or foil having a constant thickness, for example, a thickness ranging from about 0.05 mm to about 0.2 mm, and thus, manufacturing costs thereof are low.

The main body 110 may be formed from a high strength metal sheet or metal foil of stainless steel, copper, a copper alloy, aluminum, or magnesium through a pressing process or a drawing process, particularly, a deep drawing process, thereby resisting external force or shock. The outermost layer of the main body 110 including the flanges 120 may be plated with stannum (Zn), a stannum alloy, or silver (Ag) in order to facilitate a soldering process using solder cream. At this point, portions of the flanges 120 defining the through holes 122 are also plated with stannum or silver, thus ensuring the electrical and mechanical soldering of the solder members 130 to the flanges 120, the solder cream, and the ground pattern during the reflow soldering process.

Alternatively, the main body 110 may be formed from a heat resistant polymer film including a metal layer. In this case, the outermost layer of the metal layer may be plated with stanuum in order to facilitate the reflow soldering process using the solder cream.

When the main body 110 is formed from a heat resistant polymer film, the main body 110 is lightweight and is efficiently processed. Moreover, a side surface of the shield case 100 may be insulated.

The main body 110 may have a box shape with a tetragonal, polygonal, or circular shape in plan view. However, the shape of the main body 110 is not limited thereto, and thus, may have a box shape with upper and lower openings, which will be described later.

The top surface of the main body 110 may be at least partially flat to facilitate the vacuum pickup process, and may be provided with heat emission holes for emitting heat.

The flanges 120 may be horizontally flat, and extend outward or inward from the main body 110. In particular, when the flanges 120 extend inward from the shield case 100, the space of the printed circuit board taken by the shield case 100 can be decreased

FIG. 3 is a perspective view illustrating a shield case for electromagnetic wave shielding which includes a modified example of the flanges of FIG. 2.

Referring to FIG. 3, when a shield case 200 is small, flanges 220, 222, 224, 226, and 228 including through holes 221 are disposed on only a portion of opening edges of a main body 210, and solder members are placed in the through holes 221, thereby decreasing a space taken by the shield case 200.

That is, the flange 220 may be formed in a desired shape on only a portion of the main body 210 according to a purpose thereof.

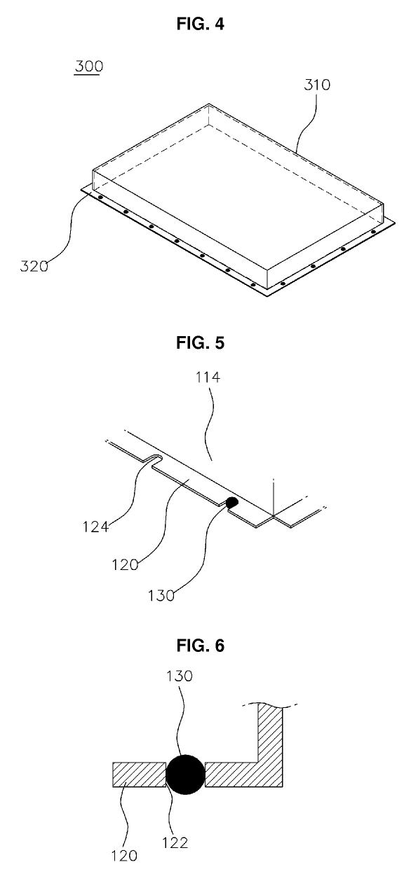

FIG. 4 is a perspective view illustrating a shield case for electromagnetic wave shielding, which includes another modified example of the flanges of FIG. 2.

A flange 320 of a shield case 300 extends outward from opening edges of a main body 310 of the shield case 300, and is continuous along the opening edges.

The shield case 300 may be formed from a metal sheet or foil through a drawing process (also called a forming process). In this case, while mold costs are expensive, the shield case 300 is excellent in mechanical strength and dimensional stability.

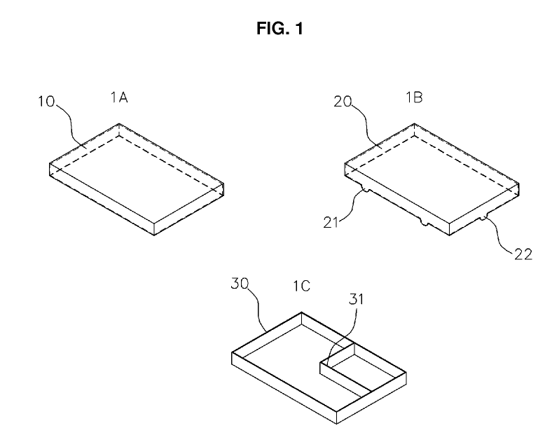

Referring again to FIG. 1, since the flanges 120 have a width greater than the thickness of a side wall 114 of the main body 110, when the surface mounting process using vacuum pickup and the reflow soldering process are performed, a moving amount of the shield case 100 on the solder cream formed on the ground pattern of the printed circuit board is small, thus facilitating the reflow soldering process. In addition, the contact area between the shield case 100 and the contact pattern is increased to improve electromagnetic wave shield efficiency and mechanical adhesion strength. In addition, forming of the through holes 122 is facilitated. For example, the width of the flanges 120 may range from about 0.5 mm to about 2.5 mm in consideration of the thickness of the side wall 114, the diameter of the through holes 122, and the diameter of the solder members 130.

Each of the flanges 120 extending from the side wall 114 may be provided with at least one of the through holes 122. For example, the through holes 122 may be arrayed to laterally or vertically balance the shield case 100 when being mounted, and be the same in shape and dimension.

The through holes 122 may have a closed shape such as a circle or oval or an open shape with an open side in consideration of soldering strength after the reflow soldering process, the width of the flanges 120, and economic feasibility. In particular, when the through holes 122 have an oval shape or an open shape with an open side, surface tension efficiently occurs from the solder cream and the solder members 130 molten during the reflow soldering process, to thereby obtain excellent soldering strength.

FIG. 5 is a partial perspective view illustrating a shield case for electromagnetic wave shielding, which includes a modified example of the through holes of FIG. 1.

Referring to FIG. 5, through holes 124 have a circular shape or an oval shape with an opening at an edge of flanges 120. This configuration is appropriate for a case that the flanges 120 have a small width, and facilitates installation of solder members 130.

In addition, this configuration improves solder-rising of solder cream in a reflow soldering process.

FIG. 6 is a cross-sectional view taken along line A-A′ of FIG. 2.

Referring to FIG. 6, the through hole 122 vertically extends, and the solder member 130 are placed therein. During the reflow soldering process, the solder member 130 is soldered to the solder cream formed on the ground pattern, and stannum formed on the flange 120. The solder member 130 may be installed in the through hole 122 through mechanical insertion, soldering using solder cream, adhesion using an electrically conductive adhesive, welding using heat, or a combination thereof.

For example, a chip mounter may supply the solder member 130 to the through hole 122 with solder cream applied, and then, the solder member 130 may be placed within the through hole 122 through a reflow soldering process.

Since the solder member 130 protrudes from the through hole 122 disposed in the flange 120, the solder member 130 and the solder cream contact each other and are molten during the reflow soldering process, so that the solder member 130 and the solder cream are reliably and electrically connected to each other, and desired mechanical adhesion strength therebetween is obtained. That is, the solder member 130 protruding from the outer or back surface of the flange 120 reliably contacts the solder cream during the surface mounting process, thereby improving soldering strength of the shield case 100 through the reflow soldering process.

To balance the soldering strength of the shield case 100, the through holes 122 of the flanges 120 opposed to each other are symmetrically arrayed.

Since the solder members 130 are placed within the through holes 122 as described above, the shield case 100 reliably and electrically contacts the solder cream with desired mechanical strength through the reflow soldering process. That is, the solder members 130 compensate for an insufficient amount of the solder cream, and functions as solder sufficiently supplied into the through holes 122.

For example, the solder member 130 may be a spherical solder ball used for a typical semiconductor ball grid array (BGA) package, but is not limited thereto. Thus, the solder member 130 may be a cylindrical or hexahedron element formed of a metal, ceramic, or a heat resistant polymer resin with both ends plated with stannum or silver, and appropriate for a soldering process including reflow soldering.

For example, the solder ball may be a spherical solder ball manufactured with a ratio of 96.5Sn/3.5Ag by the Alpha Metal company, but is not limited thereto. Thus, the solder ball may be a copper (Cu) core solder ball including an inner copper ball plated with stannum. When the copper core solder ball is used as the solder member 130, material costs and electrical resistance thereof are decreased, and the inner copper ball prevents the copper core solder ball from being molten down during a soldering process. Furthermore, stanuum formed on the inner copper ball is efficiently soldered to solder cream.

When the solder member 130 is a spherical solder ball, the solder member 130 may have a diameter ranging from about 0.3 mm to about 1.5 mm in consideration of the width of the flange 120 and economic feasibility.

The shield case 100 configured as described above facilitates both the surface mount process using vacuum pickup and the reflow soldering process using solder cream, thereby improving reliability, productivity, and economic feasibility.

In addition, since the solder members 130 are placed in advance in the through holes 122, the shield case 100 can be reliably and economically soldered to a ground pattern of a printed circuit board.

In addition, the shield case 100 is excellent in mechanical strength, mechanical coupling strength, and heat emission.

In addition, since the width of the flanges 120 adhered to a ground pattern is great, electromagnetic wave shield efficiency is improved, and forming of the through holes 122 is facilitated, Furthermore, a moving amount of the shield case 100 during a reflow soldering process is small.

In addition, since flanges may be selectively formed, the area of a printed circuit board taken by the shield case 100 can be decreased, and a reworking process using heat is facilitated.

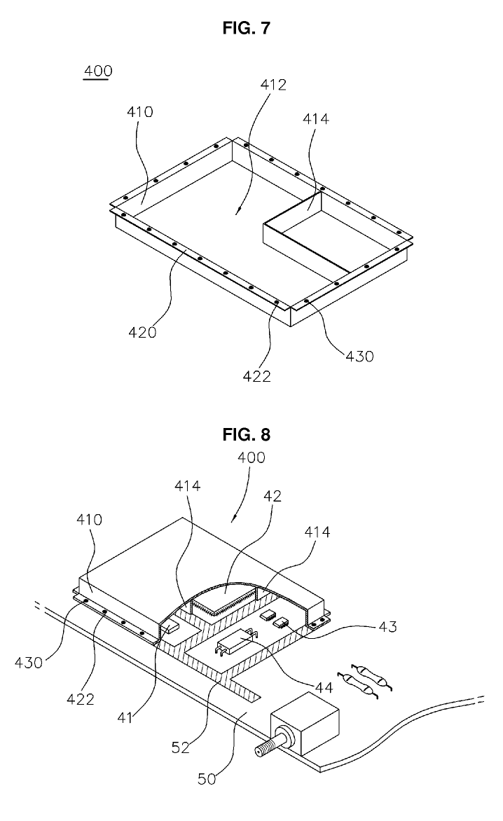

FIG. 7 is a perspective view illustrating a shield case that is easily soldered and is used for electromagnetic wave shielding, according to another embodiment of the present invention.

Referring to FIG. 7, an electromagnetic wave shield partition 414 is disposed in an inner space 412 of a main body 410 of a shield case 400.

Forming of the electromagnetic wave shield partition 414 is as follows. First, electrically insulating liquid silicone rubber paste is mixed with metal powder such as copper, nickel, or silver, or with electrically conductive carbon powder, then, the liquid silicone rubber paste is stacked on a bottom surface of the inner space 412, and then, is cured with heat, moisture, or ultraviolet rays.

At this point, a dispenser is used to stack the liquid silicone rubber paste on the bottom surface of the inner space 412. After that, during the curing of the liquid silicone rubber paste, the liquid silicone rubber paste is adhered to the bottom surface of the inner space 412 through a self adhesion process to form the electromagnetic wave shield partition 414 that has elasticity.

The electromagnetic wave shield partition 414 may have a Shore A hardness ranging from about 30 to 60 and a resilient rate of about 85% or greater, so that the electromagnetic wave shield partition 414 can be efficiently and elastically adhered to a ground pattern with small force.

The electromagnetic wave shield partition 414 may have a vertical electric resistance of about 1 ohm or less.

The electromagnetic wave shield partition 414 may have a width ranging from about 0.4 mm to about 2 mm, and a height equal to or slightly greater than the height of a side wall of the main body 410, so that the electromagnetic wave shield partition 414 of the shield case 400 mounted on a printed circuit board through a reflow soldering process can reliably contact a ground pattern disposed inside the shield case 400 and is electrically connected thereto.

After flanges 420 of the shield case 400 are soldered to the ground pattern, the electromagnetic wave shield partition 414 disposed on a back surface of the shield case 400 blocks electromagnetic waves between electronic parts or modules disposed inside the shield case 400.

The position and size of the electromagnetic wave shield partition 414 can be conveniently and economically determined according to a dispensing process. Thus, even when the positions of electronic parts or modules on a printed circuit board are changed, the electromagnetic wave shield partition 414 can be conveniently formed to correspond to the changed positions.

In addition, the electromagnetic wave shield partition 414 increases mechanical strength of the shield case 400 and absorbs shock.

FIG. 8 is a perspective view illustrating a state in which the shield case 400 of FIG. 7 is attached through a reflow soldering process to solder cream formed on a ground pattern of a printed circuit board.

The flanges 420 horizontally and outwardly extend along opening edges of the shield case 400, and are integrally formed with the shield case 400 in one piece. Through holes 422 are arrayed along the flanges 420. Alternatively, the flanges 420 may horizontally and inwardly extend along the opening edges of the shield case 400 with the through holes 422 arrayed along the flanges 420.

Although the number of the through holes 422 or the distances therebetween are not specifically limited, the through holes 422 may be symmetrically arrayed in each of the flanges 420 so as to reliably ensure soldering strength.

Solder members 430 such as solder balls may be forcibly fitted in the through holes 422 of the flanges 420, or be soldered thereto, and thus, can be prevented from being removed therefrom.

As described above, when the shield case 400 is mounted on solder cream over a circuit pattern 52 through a surface mount process, and a reflow soldering process is performed, the solder cream and metal plated layers disposed in the outermost portions of the solder members 430 are soldered to each other through a reflow operation. Thus, the shield case 400 is reliably, electrically and mechanically mounted on a printed circuit board 50.

At this point, the electromagnetic wave shield partition 414 elastically and electrically contacts the ground pattern 51 disposed in the shield case 400, and separates electronic parts or modules disposed in the shield case 400 from one another so as to block electromagnetic waves therebetween.

The ground pattern 52 contacting the solder members 430 of the shield case 400 may be provided with recesses or via halls (not shown) that have a size to receive a protruded portion of the solder members 430. Thus, the solder members 430 protruding from the flanges 420 contact the ground pattern 52 without a gap.

The recesses or via holes of the ground pattern 52 decrease a moving amount of the shield case 400 during the reflow soldering process, thereby improving the reliability of soldering.

Furthermore, after the reflow soldering process, the flanges 420 of the shield case 400 more tightly contact the ground pattern 52 by means of the recesses or via holes.

As described above, when a shield case includes solder balls and through holes uniformly arrayed in wide flanges, and is appropriate for a reflow soldering process, the shield case can be economically and reliably soldered, through the reflow soldering process, to solder cream over a ground pattern of a complicated and large printed circuit board.

In addition, the shield case is appropriate for a surface mount process using vacuum pickup, thus improving productivity.

As a result, according to the present invention, solder members appropriate for reflow soldering are disposed in advance within wide through holes of a shield case for electromagnetic wave shielding, so that a surface mount process using vacuum pickup, and a reflow soldering process using solder cream can be reliably and economically performed.

In addition, since the position, structure, and shape of flanges of the shield case is efficiently set according to purposes thereof, electrical performance and mechanical coupling strength of the shield case are improved.

In addition, reworking of the shield case is facilitated.

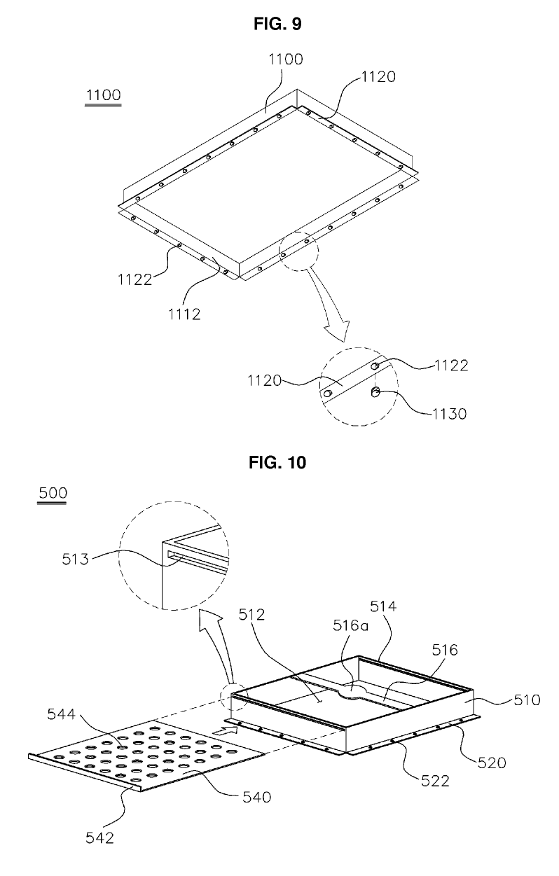

FIG. 9 is a perspective view illustrating the lower part of a shield case for electromagnetic wave shielding, according to another embodiment of the present invention.

Flanges 1120 extend outward from edges of an opening 1112 of a main body 1100.

According to the current embodiment, recesses 1122 are arrayed along the flange 1120 in the back surface thereof. The recesses 1122 have a circular shape, but the shape thereof is not limited thereto, and thus, the recesses 1122 may have a tetragonal shape or a polygonal shape.

Solder pellets 1130 having a cylindrical shape may be placed in the recesses 1122 through mechanical insertion, soldering using solder cream, welding using heat, or a combination thereof, as described above. Furthermore, the solder pellets 1130 may be placed in the recesses 1122 through an electrically conductive adhesive applied in the recesses 1122.

However, the present invention is not limited thereto, and thus, the solder pellets 1130 may be solder balls.

As described above, the shape of the recesses 1122 may be varied, and the shape of the solder pellets 1130 may also be varied with the shape of the recesses 1122. For example, when the recess 1122 has tetragonal shape, a hexahedron chip having both ends to which stannum or silver appropriate for reflow soldering is attached may be used as the solder pellet 1130.

For example, the solder pellets 1130 may protrude from the recesses 1122. In this case, the solder pellets 1130 are reliably, electrically, and mechanically attached to solder cream formed on a ground pattern.

FIG. 10 is a perspective view illustrating a shied case 500 for electromagnetic wave shielding, according to another embodiment of the present invention.

A main body 510 of the shield case 500 includes: a plurality of flanges 520 on which solder members 522 are placed; an upper opening 512; and a lower opening. The upper opening 512 is covered with a metal cover 540. The current embodiment is the same as the previous embodiments in that the flanges 520 extend outward or inward along edges of the lower opening of the main body 510, and are integrally formed with the main body 510 in one piece, and through holes 522 are arrayed along the flanges 520, or recesses are disposed in the back surfaces of the flanges 520.

Slots 513 and 514 are adjacent to the upper ends of face-to-face side walls of the main body 510, and correspond to the respective entire widths of the side walls. The metal cover 510 is inserted in the slots 513 and 514, and is slid in the direction of an arrow of FIG. 10 so as to cover the upper opening 512 of the main body 510.

After the main body 510 is soldered to a printed circuit board, the metal cover 540 is installed in the main body 510.

Alternatively, the slot 513 may be disposed in the front one of the side walls, and an emboss line (not shown) replacing the slot 514 may protrude from the rear one of the side walls to support the metal cover 510 from the lower side thereof.

A bridge 516 crosses the upper opening 512 of the main body 510. A pickup land 516a is disposed in the middle of the bridge 516. The pickup land 516a may be used to pick up the main body 510 through a vacuum pickup process.

The bridge 516 may be higher or lower than the slots 513 and 514. For convenience in a manufacturing process, the bridge 516 and the upper end of the side walls may be disposed at the same level that is higher than the slots 513 and 514.

Under this structure, the main body 510 without the metal cover 540 is picked up through a vacuum pickup process to solder the flanges 520 to a ground pattern of a printed circuit board through a reflow soldering process, then, a vision inspection process is performed through the upper opening 512, and then, the metal cover 540 is inserted in the slots 513 and 514 to cover the upper opening 512.

For example, heat emitting holes 542 for emitting heat may be disposed in the metal cover 540, and a support 544 for efficiently pushing the metal cover 540 may stand upright on the front end of the metal cover 540, and be integrally formed with the metal cover 540 in one piece.

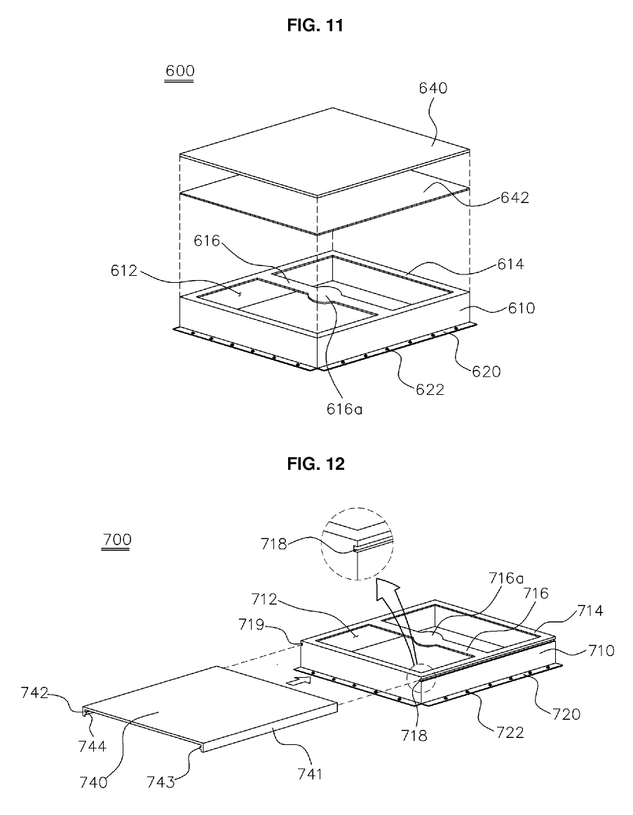

FIG. 11 is a perspective view illustrating a shied case for electromagnetic wave shielding, according to another embodiment of the present invention.

According to the current embodiment, a flange 614 extends inward from edges of an upper opening 612 of a main body 610, and is integrally formed with the main body 610 in one piece, and a metal cover 640 is adhered to the flange 614 with an electrically conductive adhesive tape 642 therebetween.

The current embodiment is the same as the previous embodiments in that flanges 620 extend outward or inward along edges of a lower opening of the main body 610, and are integrally formed with the main body 610 in one piece, and through holes 622 are arrayed along the flanges 620, or recesses are disposed in the back surfaces of the flanges 620.

As in the embodiment of FIG. 9, a bridge 616 may cross the upper opening 612, and a pickup land 616a for vacuum pickup may be provided.

The adhesive tape 642 is adhered to the entire back surface of the metal cover 640, but the present invention is not limited thereto, and thus, the adhesive tape 642 may be adhered to an area corresponding to the flange 614, the bridge 616, and the pickup land 616a.

Alternatively, the flange 614 may extend outward from the upper opening 612.

Under this structure, the flanges 620 of the main body 610 without the metal cover 640 are soldered to a ground pattern of a printed circuit board through a reflow soldering process, then, a vision inspection process is performed through the upper opening 612, and then, the metal cover 640 is adhered and fixed to the flange 614 to cover the upper opening 612.

FIG. 12 is a perspective view illustrating a shied case for electromagnetic wave shielding, according to another embodiment of the present invention.

Referring to FIG. 12, a main body 710 of a shield case 700 has an upper opening 712 and a lower opening, and the upper opening 712 is covered with a metal cover 740. Flanges 720 extend outward or inward along edges of the lower opening of the main body 710, and are integrally formed with the main body 710 in one piece. Through holes 722 are arrayed along the flanges 720, or recesses are disposed in the back surfaces of the flanges 720.

A bridge 716 crosses the upper opening 712, and a pickup land 716a for vacuum pickup is provided.

Grooves 718 and 719 for coupling the metal cover 740 to the main body 710 are adjacent to the upper ends of face-to-face side walls of the main body 710, and are continuous along the face-to-face side walls, respectively. Ribs 743 and 744, corresponding to the grooves 718 and 719 to couple to the grooves 718 and 719, protrude from the inner portions of both side walls 741 and 742 of the metal cover 740.

Under this structure, the metal cover 740 is horizontally slid and coupled to the main body 710 along side surfaces of the main body 710 with the ribs 743 and 744 aligned with the grooves 743 and 744 disposed in the side walls 711 and 712 of the main body 710.

The grooves 718 and 719, and the ribs 743 and 744 have tetragonal cross sections, but are not limited thereto.

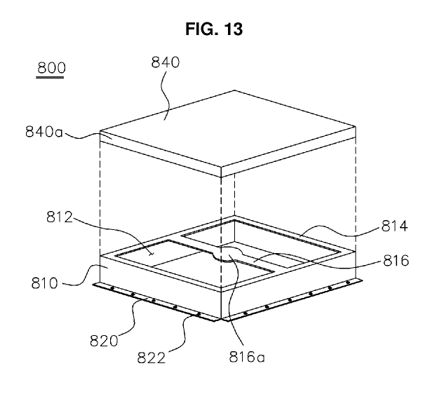

FIG. 13 is a perspective view illustrating a shied case for electromagnetic wave shielding, according to another embodiment of the present invention.

A main body 810 of a shield case 800 has an upper opening 812 and a lower opening, and the upper opening 812 is covered with a metal cover 840. Flanges 820 extend outward or inward along edges of the lower opening of the main body 810, and are integrally formed with the main body 810 in one piece. Through holes 822 are arrayed along the flanges 820, or recesses are disposed in the back surfaces of the flanges 820.

A bridge 816 crosses the upper opening 812, and a pickup land 816a for vacuum pickup is provided.

A side wall 840a extends along the four edges of the metal cover 840 to couple the metal cover 840 to the main body 810, and is integrally formed with the metal cover 840 in one piece. The inner portion of the side wall 840a is mechanically fitted on the upper opening 812 to cover the upper opening 812.

The flanges 714 and 814, extending along the upper opening 712 and 812 of the main body 710 and 810, just function as a reinforcement for the upper opening 712 and 812, and thus, can be removed.

According to the embodiments of FIGS. 10 to 13, the solder members are placed in the through holes or recesses disposed in the flanges extending from the metal main body in one piece, and the upper opening is disposed in the top of the metal main body to emit heat or visually inspect electronic parts therein. Thus, reflow soldering is facilitated through a surface mount process, and electronic parts or modules disposed in the shield case can be efficiently and visually inspected before and after the reflow soldering.

In addition, heat generated during the reflow soldering process is transferred to the inside of the shield case through the upper opening of the main body, and thus, an electronic part disposed outside the shield case and an electronic part disposed inside the shield case have a similar soldering temperature, so that the reflow soldering process can be simultaneously performed on both the electronic parts inside and outside the shield case, thereby improving productivity.

In addition, since a vision inspection process can be performed before and after the reflow soldering, a reworking process can be efficiently performed. In addition, after the vision inspection process and the reworking process, the main body can be efficiently covered with the metal cover.

While the present invention has been described in detail, it should be understood that various changes, substitutions and alterations can be made hereto without departing from the spirit and scope of the invention as defined by the appended claims.

1. An easily solderable shield case for electromagnetic wave shielding, comprising:
a main body formed of a metal, and having a box shape with a lower opening;
a flange extending outward or inward from an edge of the lower opening of the main body, and integrally formed with the main body in one piece;
a plurality of through holes arrayed along the flange or a plurality of recesses arrayed along a back surface of the flange; and
a plurality of solder members placed in the through holes or the recesses and protruding in a thickness direction of the flange,
wherein the shield case is mounted on a ground pattern of a printed circuit board, and the solder members are electrically and mechanically connected to the ground pattern through soldering.

2. The easily solderable shield case of claim 1, wherein the main body is formed from a metal sheet having a constant thickness, through a pressing process or a drawing process.

3. The easily solderable shield case of claim 1, wherein the main body is formed of stainless steel, copper, a copper alloy, aluminum, or magnesium, or is formed by adhering a heat resistant polymer film including a metal layer, to a lower surface of a metal sheet.

4. The easily solderable shield case of claim 1, wherein the flange is plated with stannum or an stannum alloy.

5. The easily solderable shield case of claim 1, wherein the flange is disposed on at least one portion of the edge of the lower opening of the main body.

6. The easily solderable shield case of claim 1, wherein the flange is horizontal.

7. The easily solderable shield case of claim 1, wherein the through holes or the recesses have a circular shape with a diameter smaller than that of the solder members.

8. The easily solderable shield case of claim 1, wherein the solder members have a spherical shape, a cylindrical shape, or a hexahedron shape, and are formed of a material appropriate for reflow soldering.

9. The easily solderable shield case of claim 1, wherein the solder members comprise solder balls or chips having both ends to which stannum or silver appropriate for reflow soldering is attached.

10. The easily solderable shield case of claim 1, wherein the solder members are placed in the through holes or the recesses through mechanical insertion, soldering using solder cream, adhesion using an electrically conductive adhesive, welding using heat, or a combination thereof.

11. The easily solderable shield case of claim 1, wherein a top of the main body is closed, or has a heat emission hole or a hole for visually inspecting an electronic part disposed in the shield case.

12. The easily solderable shield case of claim 1, wherein at least one portion of a top surface of the main body is flat to be appropriate for a surface mount process using vacuum pickup.

13. The easily solderable shield case of claim 1, wherein an electromagnetic wave shield partition protrudes from an inner portion of a top of the main body to define an electromagnetic wave shield area.

14. The easily solderable shield case of claim 13, wherein the electromagnetic wave shield partition is formed of electrically conductive silicone rubber.

15. The easily solderable shield case of claim 1, wherein the mounting of the shield case is done by a surface mount process using vacuum pickup, and the soldering is reflow soldering.

16. An easily solderable shield case for electromagnetic wave shielding, comprising:
a main body formed of a metal, and having a box shape with a lower opening;
a flange extending outward or inward from an edge of the lower opening of the main body, and integrally formed with the main body in one piece;
a plurality of through holes arrayed along the flange or a plurality of recesses arrayed along a back surface of the flange; and
a plurality of solder members appropriate for reflow soldering, which are placed in the through holes or the recesses, and protrude in a thickness direction of the flange.

17. An easily solderable shield case for electromagnetic wave shielding, comprising:
a main body formed of a metal, and having a box shape with a lower opening;
a flange extending outward or inward from an edge of the lower opening of the main body, and integrally formed with the main body in one piece;
a plurality of through holes arrayed along the flange or a plurality of recesses arrayed along a back surface of the flange; and
a plurality of solder members placed in the through holes or the recesses and protruding in a thickness direction of the flange,
wherein the solder members are electrically and mechanically connected to a ground pattern of a printed circuit board through a reflow soldering process and a surface mount process using vacuum pickup.

18. An easily solderable shield case for electromagnetic wave shielding, comprising:
a main body formed of a metal, and having a box shape with an upper opening and a lower opening;
an electrically conductive cover that covers the upper opening of the main body and is removable therefrom;
a flange extending outward or inward from an edge of the lower opening of the main body, and integrally formed with the main body in one piece;
a plurality of through holes arrayed along the flange or a plurality of recesses arrayed along a back surface of the flange; and
a plurality of solder members placed in the through holes or the recesses and protruding in a thickness direction of the flange,
wherein the main body is mounted on a ground pattern of a printed circuit board, and is electrically and mechanically connected to the printed circuit board through a soldering process using the solder members, and the electrically conductive cover is installed on the main body after the soldering process.

19. The easily solderable shield case of claim 18, wherein the electrically conductive cover has a sheet shape, and is inserted in a slot disposed in a side wall of the main body to cover the upper opening.

20. The easily solderable shield case of claim 18, wherein side walls extends from four edges of the electrically conductive cover, and are integrally formed with the electrically conductive cover in one piece, and
the side walls are mechanically fitted on the upper opening of the main body to cover the upper opening.

21. The easily solderable shield case of claim 18, wherein the electrically conductive cover has a sheet shape, and covers the upper opening of the main body with an electrically conductive adhesive tape therebetween.

22. The easily solderable shield case of claim 18, wherein grooves are adjacent to upper ends of face-to-face side walls of the main body, and are continuous along the face-to-face side walls, respectively,
ribs, corresponding to the grooves to couple to the grooves, protrude from inner portions of both side walls of the electrically conductive cover, and
the electrically conductive cover is coupled to the main body by aligning the ribs with the grooves.

23. The easily solderable shield case of claim 18, wherein face-to-face edges of the upper opening are connected to each other through a bridge, and
a pickup land for vacuum pickup is disposed at a middle portion of the bridge.

24. The easily solderable shield case of claim 18, wherein the upper opening is used to emit heat and to visually inspect an electronic part disposed in the shield case.

25. The easily solderable shield case of claim 1, wherein solderable via holes or solderable recesses are disposed in the ground pattern on which the solder members are mounted.

26. The easily solderable shield case of claim 16, wherein solderable via holes or solderable recesses are disposed in the ground pattern on which the solder members are mounted.

27. The easily solderable shield case of claim 17, wherein solderable via holes or solderable recesses are disposed in the ground pattern on which the solder members are mounted.

28. The easily solderable shield case of claim 18, wherein solderable via holes or solderable recesses are disposed in the ground pattern on which the solder members are mounted.
